(19) United States
(12) Patent Application Publication
(10) Pub. No.: US 2022/0216811 A1
(43) Pub. Date: Jul. 7, 2022

(54) ENERGY HARVESTING SYSTEM

(71) Applicant: TDK Electronics AG, München (DE)

(72) Inventors: Marcin Brylak, Gratwein-Straßengel (AT); Stefan Sax, Graz (AT); Peter Lukan, Deutschlandsberg (AT)

(21) Appl. No.: 17/608,231

(22) PCT Filed: May 15, 2020
(86) PCT No.: PCT/EP2020/063645

§ 371 Date: Nov. 2, 2021

(30) Foreign Application Priority Data
May 15, 2019 (DE) 10 2019 112 746.7

(51) Int. Cl. H02N 2/18; H01L 41/113; H02J 7/00

(52) U.S. Cl. CPC H02N 2/186; H02J 7/0042; H01L 41/113

(57) ABSTRACT

An energy harvesting system having at least two piezoelectric units and a central control unit. Each of the piezoelectric units has a piezoelectric layer and an integrated electronics unit, which contacts the piezoelectric layer. The piezoelectric layers are arranged at an angle to one another. Electrical components used to smooth the voltage generated in a piezoelectric layer are built into the integrated electronics unit. The integrated electronics unit contacts the central control unit, which in turn includes a control module and is designed to collect electrical energy from the piezoelectric units. The control module is designed to minimize or to eliminate a reciprocal electrical damping of the piezoelectric units.

The invention relates to an energy harvesting system.

The advancing miniaturization of electronic components not only reduces the dimensions of the components but also results in a reduction in the electrical energy required. Therefore, it is nowadays possible to integrate more and more functions in a device, for instance the smartphone, and also to offer electrical devices in a mobile design not yet conceivable a few years ago. Nevertheless, these mobile devices require a rechargeable battery or a battery as an energy source which regularly has to be replaced or charged using an external power supply.

Energy harvesting, in which small amounts of energy are extracted from the environment, has become established as a possible solution approach in order to allow devices which are independent in terms of energy to be supplied with energy. The best-known macroscopic example are mechanical wristwatches which, via an imbalance, use mechanical energy from the wearer to operate the watch. At microscopic levels, photovoltaics are a known example and can be used to operate an electrical device, for example a walkway light, independently of the power supply system. A lesser known microscopic alternative is to use the piezoelectric effect to extract energy from the environment. As a result of deformation of the piezoelectric material, for instance on account of pressure or vibrations, an electrical voltage can be tapped off at the piezoelectric material and can be used to supply energy.

Therefore, a piezoelectric energy harvesting system, which has a good energy yield in a plurality of spatial directions, is desirable.

The object of the present invention is to provide a piezoelectric energy harvesting system which has advantageous energy efficiency in a plurality of spatial directions.

The present object is achieved by means of the energy harvesting system according to claim 1, Further advantageous embodiments and potential arrangements can be gathered from the further claims.

An energy harvesting system having at least two piezoelectric units and a central control unit is described. The piezoelectric units in turn each have a piezoelectric layer and integrated electronics, wherein the integrated electronics make contact with the piezoelectric layer. The piezoelectric layers are arranged at an angle to one another. Electrical components which are used to smooth the voltage generated in a piezoelectric layer are installed in the integrated electronics. The integrated electronics make contact with the central control unit which in turn has a control module and is designed to collect electrical energy from the piezoelectric units, wherein the control module is designed to minimize or prevent mutual electrical damping of the piezoelectric units.

It is therefore possible to construct an energy harvesting system comprising a plurality of piezoelectric units which are used as harvesting elements, wherein the respective piezoelectric units may be oriented in different directions relative to one another. Electronics fitted to the piezoelectric units and central control electronics are used in interaction in any case—that is to say regardless of the direction from which the overall system is excited—to extract the maximum possible electrical energy. In this case, mutual electrical damping of the individual piezoelectric elements can be prevented.

This maximum energy can then be used, in particular, for system operation, as well as to transmit signals or for buffering.

The term “at an angle” can be understood here as meaning an arrangement in which the relevant layers are arranged at any desired angle, other than 0°, to one another. An angle which is enclosed by the respective surface normals of the surfaces of the layers can be considered here as the angle between the layers. The layers at an angle to one another can therefore be arranged in any desired manner with respect to one another, wherein only a parallel arrangement of the layers is excluded. The angle between the two layers arranged at an angle to one another should preferably be at least 10°, particularly preferably at least 45°.

The amount of energy which can be generated by a piezoelectric layer is greatly dependent on the degree of deformation of the piezoelectric material and is therefore closely tied to the geometry used. Particularly in geometries which result in anisotropic flexibility, for instance of a piezoelectric layer, the possible energy extracted is greatly dependent on the direction of an acting force. In the case of a piezoelectric layer, a force with a direction parallel to the normal may thus result in severe deformation and therefore great energy extraction, whereas a force of the same magnitude perpendicular to the normal does not produce any deformation and therefore any energy extraction.

By virtue of the fact that each piezoelectric unit has its own integrated electronics which smooth and limit the voltage generated in the piezoelectric layer, the voltage which is generated and often fluctuates greatly can be rendered directly usable for further electrical components and the further electrical components can be protected from a voltage spike. The control module in the control unit can be primarily used to prevent or minimize mutual electrical damping of the piezoelectric units.

The two piezoelectric layers may be perpendicular to one another. It is therefore particularly advantageous to arrange at least two piezoelectric layers not only at an angle but rather perpendicular to one another since the energy extraction not only depends on the direction of the force with respect to one of the normals of a piezoelectric layer but on the direction of the force with respect to a plane spanned by the two normals of the two piezoelectric layers. If the force acts within the plane, the energy extraction is independent of the direction of the force. This makes it possible to keep the energy extraction stable, for example in the case of force influences and movements taking place in a plane, for instance the rotation of a wheel.

The energy harvesting system may have a third piezoelectric unit, the piezoelectric layer of which is respectively at an angle to the piezoelectric layers of the first two piezoelectric units. Electrical energy can therefore be extracted from a further, third spatial direction.

If the third piezoelectric layer is arranged perpendicular to the first two piezoelectric layers, it is possible to collect the maximum energy from the further, third spatial direction. If all three piezoelectric layers are arranged orthogonal to one another, the maximum energy can be collected from each spatial direction. The orthogonal arrangement of the three piezoelectric layers makes it possible to make the energy extraction completely independent of the direction of the force influence on the system.

The energy harvesting system may additionally have further piezoelectric units, the piezoelectric layer of which is at an angle to the other piezoelectric units. In this manner, even more energy can be extracted from mechanical impacts or vibrations.

The piezoelectric layers may be in the form of circle segments. Piezoelectric layers in the form of circle segments make it possible to arrange plurality of layers in a plane without any gaps, with the result that the entire area can be optimally used to generate energy.

Furthermore, the piezoelectric layers may be arranged in three intersecting circular planes. In one preferred embodiment, the three planes may intersect at a right angle with respect to one another. The generation of energy therefore becomes independent of the direction since the sum of the energy generated from the piezoelectric layers in the three planes is the same irrespective of the orientation of the energy harvesting system.

It may be expedient to fasten the piezoelectric units and the control unit in a frame in order to increase the mobility of the energy harvesting system. Vibrations and force effects which act on the frame are transmitted to the piezoelectric layers, as a result of which the latter can generate electrical energy. One possibility is a fastening with screws which itself provides a fixed connection in the case of permanent vibrations. A further possibility is a fastening with an adhesive. Depending on the expected force effects on the energy harvesting system, the frame should ne stable enough to also repeatedly withstand these effects without damage. Reinforcement of the frame with reinforcing elements, in particular also at corners, can further increase the stability and robustness of the frame. Plastics and metals can be used as the material, without excluding other materials.

A configuration of the frame may be spherical. A spherical shape allows the energy harvesting system to generate electrical energy using a rolling movement, for example. In addition, a spherical energy harvesting system is also suitable for use in a sports ball, for instance a football, a basketball, a tennis ball, a baseball or a bowling ball.

Furthermore, the at least two sets of integrated electronics may be connected in parallel or in series with one another to form a group. Depending on the configuration and the material of the piezoelectric layers, the electrical power generated is output with a different electrical voltage and electrical current. If the integrated electronics are connected in parallel to form a group, the output electrical current of the individual integrated electronics can be added and increased overall. In contrast, in a serial connection of the integrated electronics, the output voltages of the integrated are added and therefore increased overall.

Moreover, the energy harvesting system may have a plurality of connected groups of integrated electronics, wherein the groups of integrated electronics may be connected in parallel or in series with one another. In a similar manner to individual integrated electronics which are connected in series or in parallel with one another, the output current from a plurality of groups can be added if the individual groups are connected in parallel with one another and the output voltage can be added if the individual groups are connected in series with one another.

The integrated electronics and/or the control unit may have electrical components for limiting an electrical voltage generated in the piezoelectric layer. Therefore, installed electrical components can be protected from voltage spikes which could destroy them.

Furthermore, the integrated electronics may have a rectifier. The current output from the piezoelectric layers is alternating current, the handling of which is more complicated than in the case of direct current. Thanks to the rectifier, the AC voltage from the piezoelectric layers can be converted into a smooth DC voltage which can then be used by other electrical components. Therefore, it may be expedient to implement a rectifier, which converts alternating current to direct current, in the integrated electronics.

It is possible to construct the rectifier from a connection of discrete individual diodes. Discrete individual diodes are relatively insensitive to high currents and voltages, and so a rectifier which uses these diodes likewise becomes insensitive to overloading.

On the other hand, it is likewise possible to integrate the rectifier in an integrated circuit and to connect a Zener diode in parallel with the integrated circuit. In contrast to discrete individual diodes, integrated circuits are sensitive to excessively high voltages. They can be easily damaged by overloading. The Zener diode acts as a type of fuse for the integrated circuit. In the case of excessive voltages, it ensures that the load on the integrated circuit is relieved and therefore protects it from damage. Possible feedback of output voltage to the rectifier and the piezoelectric layer is also suppressed by the Zener diode.

In a further embodiment, the rectifier may be integrated in an integrated circuit and a protective circuit may be connected in parallel with the integrated circuit. The protective circuit may comprise a voltage divider, a transistor and a capacitor, wherein the transistor and the capacitor are connected in series, and the voltage divider may be connected in parallel with the transistor and the capacitor. In this case, the transistor may be controlled by a voltage taken from the voltage divider. The voltage divider should be designed here such that the transistor is turned on before the integrated circuit is damaged. The excess charge from the piezoelectric layers is consequently stored in the capacitor connected in series and can be used after a voltage spike. Accordingly, the protective circuit described can also achieve a higher degree of efficiency than the circuit with the Zener diode since excessive voltage spikes can be used. In addition, the resistance of the capacitor for transient voltage spikes is low, as a result of which the generated charge can flow better from the piezoelectric layers. As a result, the electrical damping of the piezoelectric layer is reduced and the efficiency of the energy harvesting system is increased.

The control unit may have an RF module. The control unit can therefore wirelessly send information to a receiver.

The control unit and the RF module may be designed to be operated with the collected electrical energy from the energy harvesting system. This means that both the total energy and the voltage and the current are provided in a range which can be used for the control unit and the RF module.

The energy harvesting system may be completely autonomous in terms of energy, which means that all electrical components in the system are operated only with the energy extracted from the piezoelectric layers. This makes it possible to completely dispense with an external energy supply, and so the energy harvesting system is independent and mobile.

Furthermore, the piezoelectric layers may be arranged on a substrate which is thinner than 1 mm. On the one hand, a substrate increases the mechanical stability of the piezoelectric layers and so the latter withstand a greater force effect without damage. On the other hand, a substrate, in particular if it is too rigid, can prevent deflection and therefore deformation of the piezoelectric layer and can therefore reduce possible energy extraction. A thickness of less than 1 mm has proved to be advantageous in order to achieve a good compromise between the stability and flexibility. The thickness of the substrate should preferably not be lower than 0.2 mm.

The substrate may also be electrically conductive. Contact can therefore be made with the piezoelectric layer directly via the substrate and the substrate can be used in this manner as an electrode.

The piezoelectric layer may be adapted to the shape of the substrate. This makes it possible to cover the largest possible area of the substrate with a piezoelectric layer and to optimize the energy extraction. The substrate itself may be square, triangular, circular or in the form of a circle segment or may have any desired other shape. On the one hand, the substrate shape and therefore also the shape of the piezoelectric layer can thus be adapted for the geometrical requirements of an application. On the other hand, the voltage which is coupled out can be matched to the requirements of the following electrical components using the shape and size of the piezoelectric layers.

Otherwise, the piezoelectric units may have limiters which are designed to limit the deflection of the piezoelectric layers. In this case, a limiter is, for example, a part which covers the entire piezoelectric layer, half of the piezoelectric layer or only a quarter of the piezoelectric layer with a certain distance. The limiter is configured to mechanically limit the amplitude of the deformation or deflection of the piezoelectric layer, for example by virtue of the piezoelectric layer striking the limiter if the maximum permissible deformation has been reached. A distance of approximately 1 mm from the piezoelectric layer for a layer length of approximately 10 mm has proved to be advantageous. The limiter limits the maximum deflection of the piezoelectric layer and therefore restricts the mechanical load for the piezoelectric layer in the case of strong force influences or else for continuous operation. In addition, the limiter makes it possible to avoid large voltage spikes at the piezoelectric layers which occur in the case of severe deformation.

In addition to the control module and the RF module, the control unit may also have a DC/DC converter, to which the integrated electronics are connected. This makes it possible to convert the DC voltage, which is coupled out from the integrated electronics, into another voltage, for example a voltage required for the control or RF module. This also makes it possible to operate electrical components which cannot be directly operated with the voltage output by the piezoelectric layers.

In addition, both the integrated electronics and the control unit may have a smoothing capacitor. If the energy harvesting system does not have a DC/DC converter, a smoothing capacitor in the integrated electronics or the control unit can reduce voltage fluctuations and can therefore smooth the voltage profile. If a DC/DC converter is integrated in the control unit, the ratio of the input voltage and output voltage can be adapted on the basis of a capacitance of a first capacitor in the integrated electronics, which is electrically connected upstream of the DC/DC converter, and the capacitance of a second capacitor in the control unit, which is electrically connected downstream of the DC/DC converter.

The control module may he a system-on-a-chip (SoC) or a microcontroller. Both options make it possible to program sequences and functions in the energy harvesting system and also allow the energy harvesting system to be expanded with other electrical and programmable components. Moreover, the SoC and microcontroller are suitable for controlling RF modules.

Furthermore, the RF module may have a power-on reset time with a duration of less than 50 ms. An RF module with such a short power-on reset. time requires little energy in order to ramp up into a functional state. Therefore, RF modules with a short power-on reset time, in particular, are suitable for integration in an energy harvesting system. Low-energy Z-wave, ZigBee or Bluetooth modules are expressly suitable as the RF module since they consume little energy and can be controlled via a control module.

If the RF module is a Bluetooth transmitter, the Bluetooth transmitter may be configured to adapt the number of channels. According to the Bluetooth standard, there are 79 channels each with a frequency width of 1 MHz. The entire frequency width is not needed to transmit small packets, as a result of which the energy consumption of the energy harvesting system can be reduced by adapting the number of Bluetooth channels used.

In one preferred embodiment, the Bluetooth transmitter can transmit on a single channel. This is the smallest number of channels for which communication between the Bluetooth transmitter and a Bluetooth receiver is still possible. Accordingly, energy can be saved most of all with only one channel, depending on the number of channels.

Furthermore, the duration of a transmission signal, the transmission power and the inter-signal pause can be set in an RF module in such a manner that as little energy as possible is consumed. This can be specifically implemented differently depending on the RF module. The transmission power may be reduced, for example depending on a reception strength, to such an extent that there is still a reliable connection. The duration of a transmission signal can also be reduced and an inter-signal pause can be increased to such an extent that transmission of information is not disrupted, in order to reduce the energy consumption. If a receiver can be configured by the RF module, this receiver can be adapted to the transmission behavior of the RF module and the energy consumption can be reduced as a result with protected transmission of information.

The control unit may additionally have a rechargeable battery or a capacitor for storing energy. The energy which is extracted with the piezoelectric layers can therefore be stored and accumulated. This makes it possible to use the energy harvesting system to also operate applications and electrical components which require a greater electrical power or to use the collected energy at a later time.

In addition, the control unit may ne configured to determine an acceleration acting on the energy harvesting system in a direction-dependent manner on the basis of the voltages generated in the piezoelectric layers. Since deflection of the piezoelectric layers is primarily proportional to an acceleration acting on them, an acceleration can be inferred from the voltage generated at the piezoelectric layers. Since the piezoelectric layers are arranged perpendicular to one another, both the magnitude and the direction of the acceleration can be determined. If the piezoelectric layers are used as an acceleration sensor, it is advantageous to use a control module having an integrated analog/digital converter since the latter can read the analog voltage output from the piezoelectric layers.

The control unit may additionally have further sensors. Depending on the objective, the energy harvesting system may be expedient for many applications which require enhanced sensors. These may be, for example, GPS sensors, temperature sensors, force sensors, a humidity sensor or any other sensor.

Furthermore, the piezoelectric layer may be a polymer layer, a ceramic layer, a thin ceramic layer, a multilayer ceramic or a monolithic ceramic. As long as the layer is piezoelectric, it is suitable, in principle, for use in an energy harvesting system. A polymer or thin ceramic layer has the advantage of being more flexible than other piezoelectric layers. With a monolithic ceramic which is piezoelectric, the voltage output of the piezoelectric layer can be adapted by changing the monolithic connection.

The piezoelectric layer may be thinner than 300 μm.

Depending on the thickness of the piezoelectric layer, but also depending on other geometrical and material factors, the piezoelectric layer becomes more rigid or more flexible or more stable or more unstable. In addition, the flexibility of the piezoelectric layer, or the flexibility of the substrate, can be greatly changed on account of an arrangement of the piezoelectric layer on the substrate. From these points of view, a layer thickness of less than 300 μm has proved to be favorable for the piezoelectric layer since a thicker piezoelectric layer has a negative effect on the flexibility of a thin substrate.

An energy harvesting system according to the present invention may be integrated in a shock sensor by virtue of the energy harvesting system being connected to a frame, for example, wherein the energy harvesting system is designed to detect an impact or shock and to transmit this information to a receiver. Such a shock sensor which is autonomous in terms of energy is able to detect a strong acceleration, as caused by an impact, and to transmit it to a receiver, for example a smartphone, without being dependent on an external energy supply of a battery.

The invention is described in more detail below on the basis of schematic illustrations.

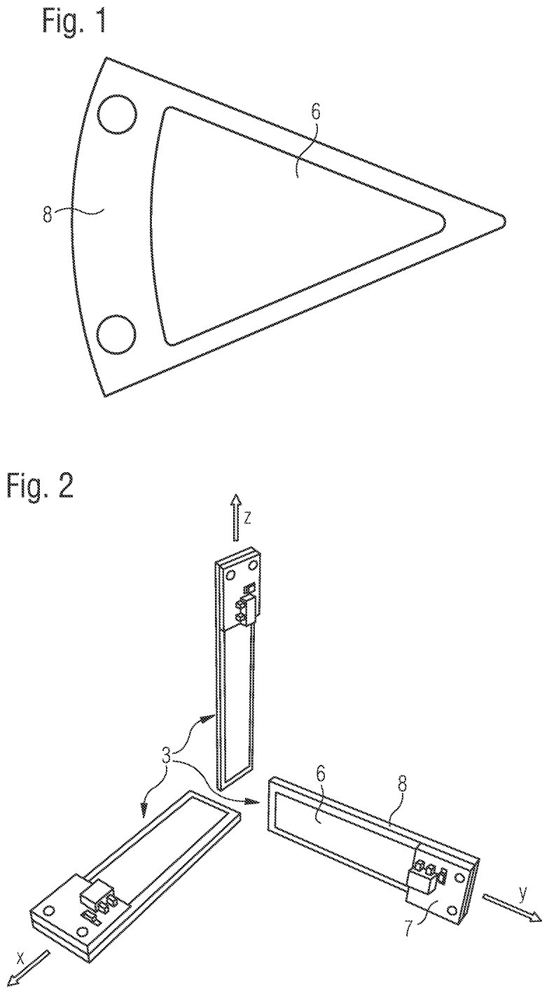

FIG. 1 shows a plan view of a piezoelectric layer which is arranged on a substrate.

FIG. 2 shows a three-dimensional view of an arrangement of three piezoelectric units.

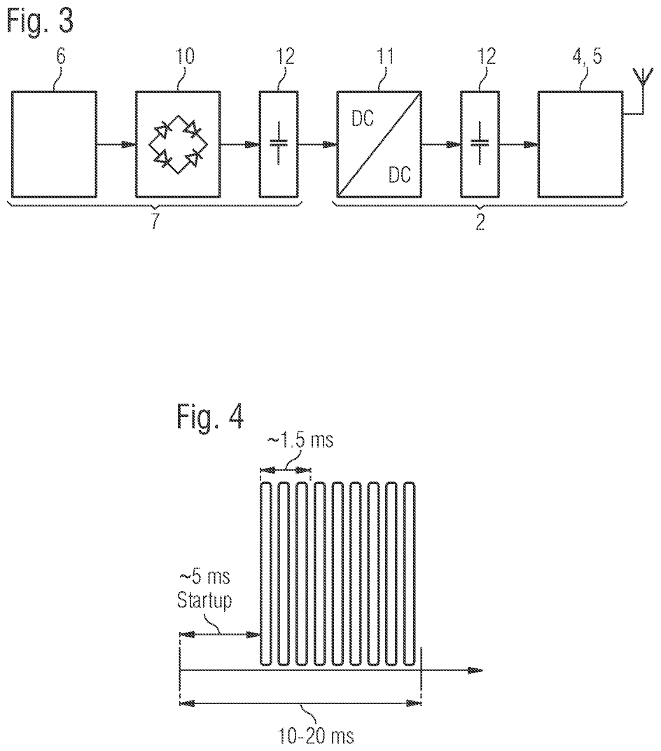

FIG. 3 shows a structure diagram of a possible arrangement of the electrical components of the integrated electronics and the control unit.

FIG. 4 is a schematic graph, wherein the transmission power of an RF module is plotted against the time.

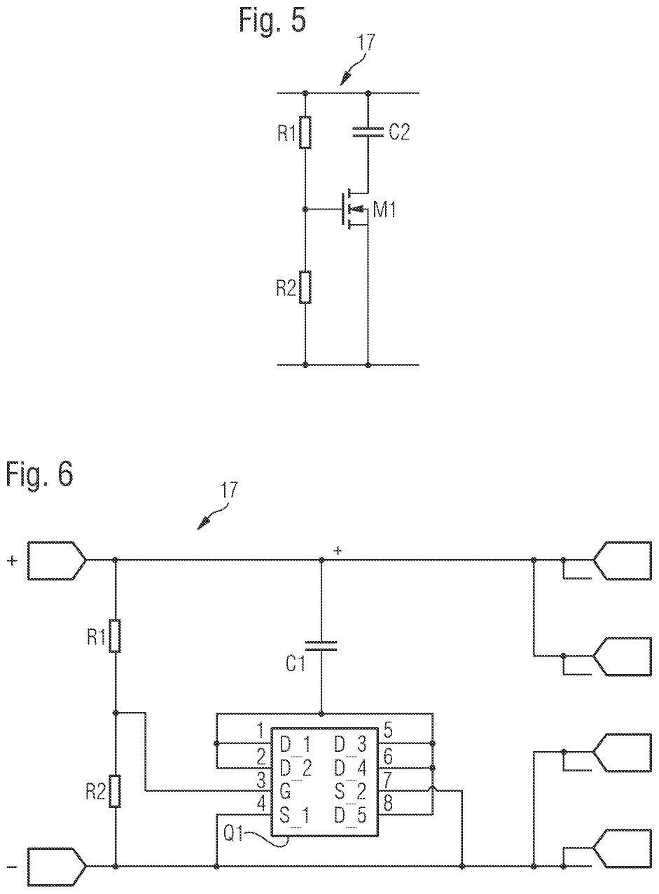

FIG. 5 shows a circuit diagram of a protective circuit.

FIG. 6 shows a circuit diagram of a protective circuit, in which the transistor is a MOSFET with eight pins.

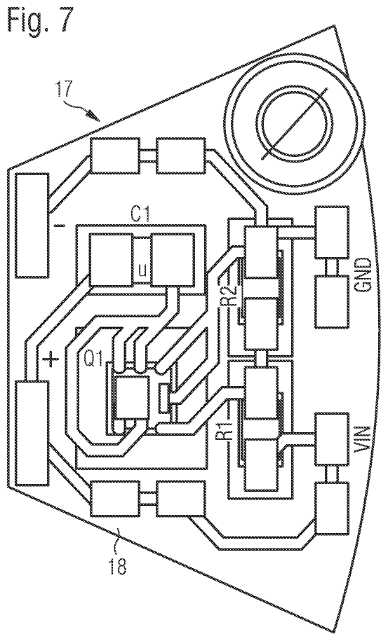

FIG. 7 shows a layout of a printed circuit board of the protective circuit from FIG. 5.

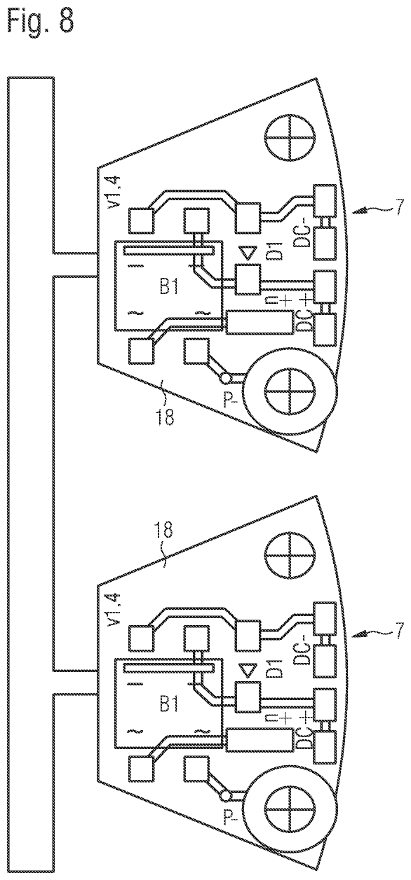

FIG. 8 shows two sets of integrated electronics which are connected in parallel.

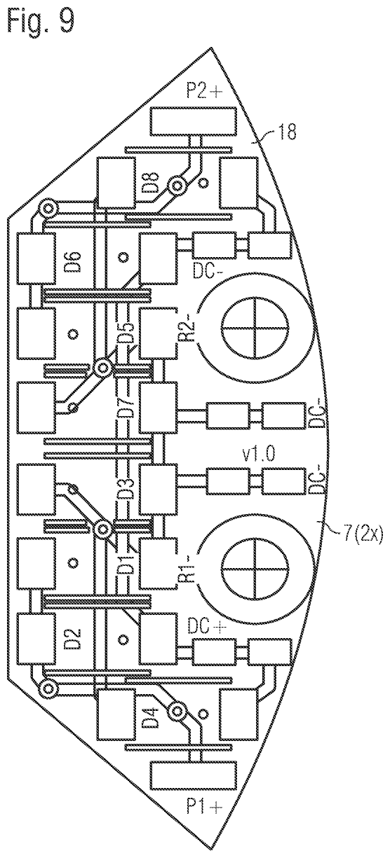

FIG. 9 shows a printed circuit board on which two sets of integrated electronics are arranged, wherein the rectifiers are constructed from eight discrete individual diodes.

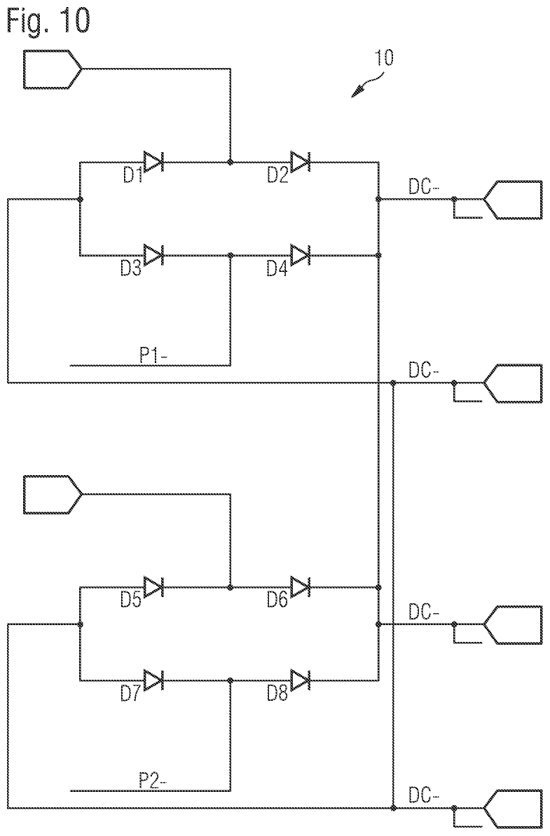

FIG. 10 shows a circuit diagram of the integrated electronics shown in FIGS. 8 and 9.

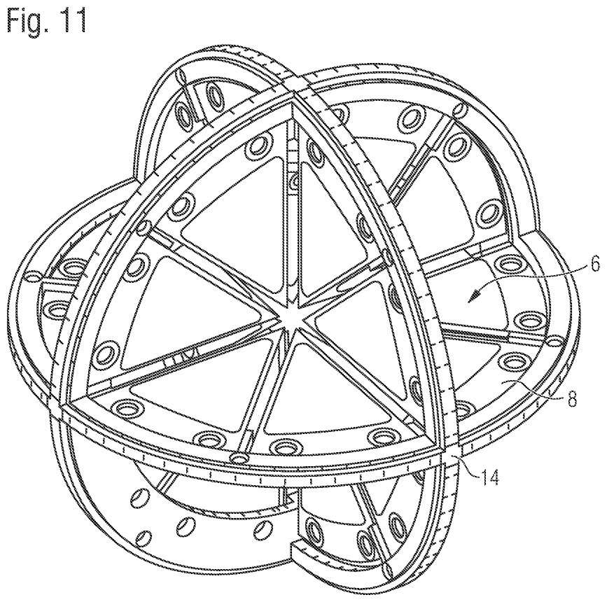

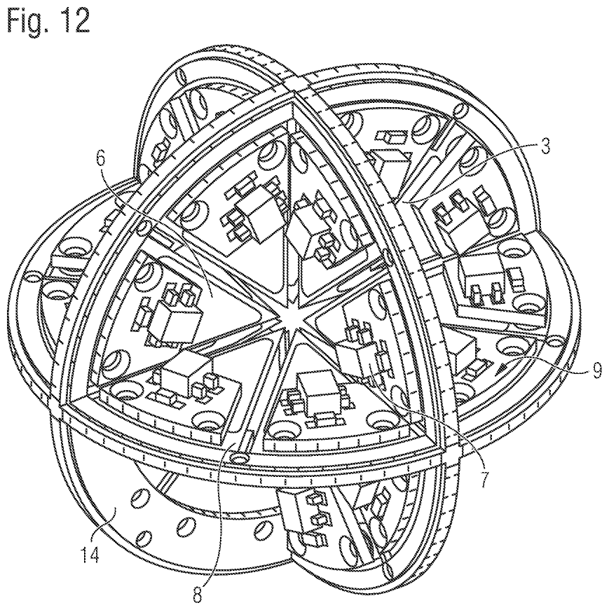

FIG. 11 shows an arrangement in which 24 piezoelectric layers are fastened in a frame.

FIG. 12 shows an arrangement in which 24 piezoelectric units are fastened in a frame.

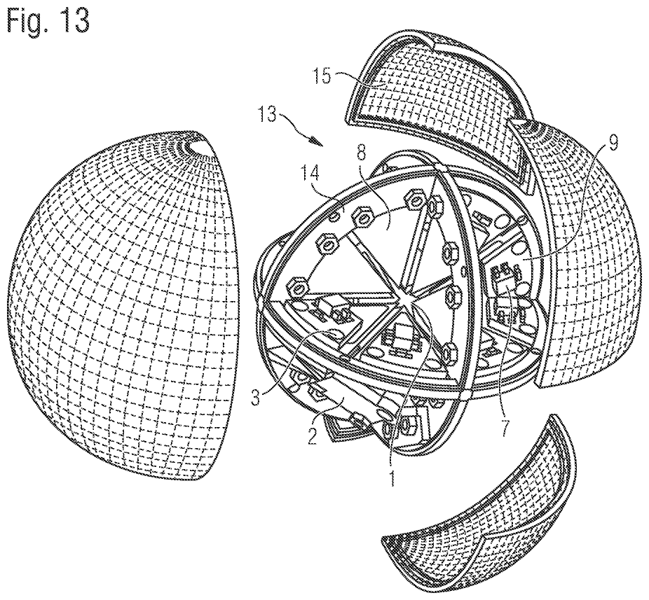

FIG. 13 shows an open shock sensor in which an energy harvesting system according to the present invention is integrated.

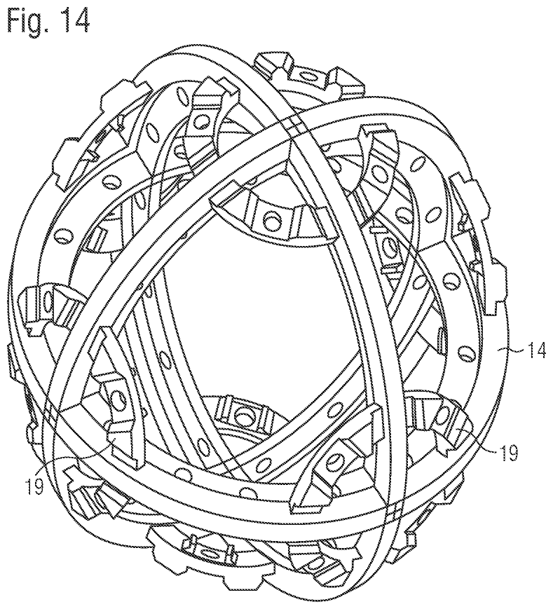

FIG. 14 shows a spherical frame which is reinforced at the corners.

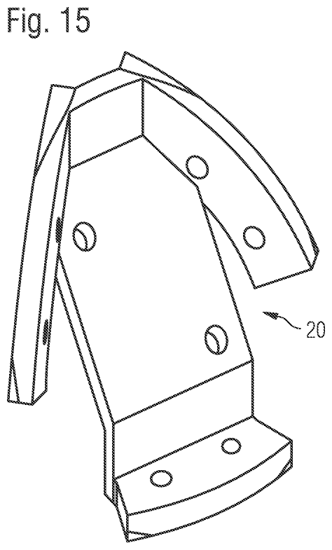

FIG. 15 shows a holder for a central control unit.

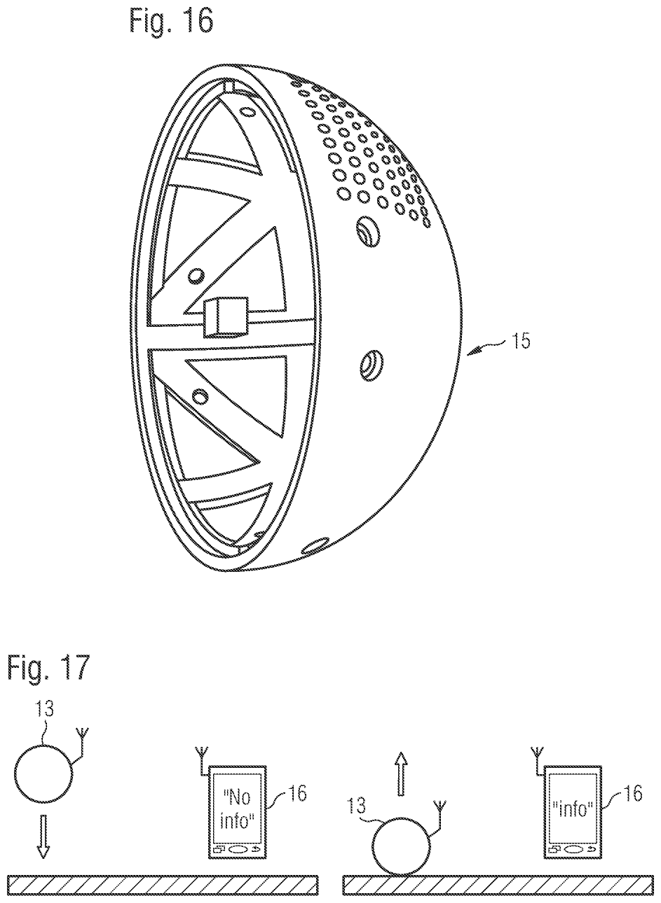

FIG. 16 shows a hemi-spherical connection for a frame with holes.

FIG. 17 shows a schematic sketch of the method of operation of a shock sensor.

Identical elements, similar or apparently identical elements are provided with the same reference signs in the figures. The figures and the proportions in the figures are not true to scale.

FIG. 1 shows a plan view of a piezoelectric layer 6 which is arranged on a substrate 8 and is suitable for an energy harvesting system 1 according to the present invention. The piezoelectric layer 6 was fastened here to the substrate 8 using an adhesive bonding method, but it is also possible to directly deposit the piezoelectric layer 6 onto the substrate 8 or to fasten it in another manner.

The piezoelectric layer 6 was adapted to the outline of the substrate 8 in the form of a circle segment in order to cover the largest possible area of the substrate 8 with a piezoelectric layer 6 and therefore to optimize the energy extraction. The substrate 8 has holes which are used to fasten the substrate 8, for example using screws. In this exemplary embodiment, although the substrate 8 in the form of a circle segment because it has been adapted to requirements of an application, it may have any other desired shape. In addition, it is possible to vary the output voltage and to adapt it to the application using the shape and size of the piezoelectric layers 6.

The piezoelectric layer 6 shown in FIG. 1 is a PZT-5H ceramic layer, but it is likewise possible to produce the piezoelectric layer 6 from another piezoelectric ceramic or to use a thin ceramic layer, a multilayer ceramic, a monolithic ceramic layer or a polymer layer. Polymer layers or thin ceramic layers have the advantage, over most other piezoelectric layers 6, that they are particularly flexible. The superiority of a monolithic ceramic layer over normal piezoelectric layers 6 is due to the fact that the voltage output can be adapted by modeling the monolithic connection in the ceramic differently.

The substrate 8 is made of steel and is therefore electrically conductive. If the piezoelectric layer 6 is arranged directly on a conductive substrate 8, as shown in FIG. 1, contact can be made with the piezoelectric layer 6 via the substrate 8 by using the substrate 8 as an electrode. In addition to steel, it would also be possible to use other metals, for example Cu, Fe or Al, or else other non-metallic conductors.

The PZT-5H layer shown in FIG. 1 has a thickness of 300 μm and the steel substrate has a thickness of 400 μm. On the one hand, a substrate 8 increases the mechanical stability of the piezoelectric layers 6 and so the latter withstand a greater force effect without damage. On the other hand, a substrate 8, in particular if it is too rigid, can hinder deflection and therefore deformation of the piezoelectric layer 6 and can therefore reduce possible energy extraction. At the same time, depending on the thickness of the piezoelectric layer 6, the piezoelectric layer 6 becomes more rigid or more flexible and more stable or more unstable. Taking these aspects into account, a layer thickness of less than 300 μm for the piezoelectric layer 6 and less than 1 mm for the substrate 8 has proved to be favorable. However, these thicknesses may change greatly depending on the material used and its elasticity.

FIG. 2 shows a three-dimensional view of an arrangement of three piezoelectric units 3, wherein the piezoelectric are arranged perpendicular to one another. Each of the three piezoelectric units 3 has a substrate 8, on which a piezoelectric layer 6 is arranged, and integrated electronics 7 which are used to smooth and limit the electrical voltage generated in the piezoelectric layer 6.

By virtue of the fact that the energy harvesting system has three piezoelectric units 3, the piezoelectric layers 6 of which are perpendicular to one another, the energy extraction is completely independent of the direction of the force influence on the system. The force component parallel to normals of the piezoelectric layer 6 is primarily important for the energy extraction of an individual piezoelectric unit 3 since this force component is decisive for the deflection of the piezoelectric layer 6 and therefore the energy extraction. For each individual piezoelectric layer 5, the force component parallel to the normal of the layer is important for the deflection, and the energy extraction is therefore independent of the direction of the force influence on account of the orthogonal arrangement of the piezoelectric layers 5.

Moreover, an acceleration acting on the energy harvesting system 1 can be determined in a direction-dependent manner on the basis of the voltages generated in the piezoelectric layers 6.

A control module 4 can calculate the acceleration from the voltages which are generated at the piezoelectric layers 5 and are dependent on the deflection and an acceleration acting on said layers. The orthogonal arrangement of the piezoelectric layers 6 makes it possible to determine both the magnitude and the direction of the acceleration. If the piezoelectric layers 6 are used as an acceleration sensor, it is advantageous to use a control module 4 having an integrated analog/digital converter since the latter is able to read the analog voltage output from the piezoelectric layers 6.

FIG. 3 shows a structure diagram of a possible arrangement of the electrical components of the integrated electronics 7 and a control unit 2, wherein the three left-hand elements belong to the integrated electronics 7 and the three right-hand elements are arranged in the control unit 2.

The voltage generated by the piezoelectric layer 6 is received by a rectifier 10, for example a bridge rectifier, which converts the fluctuating AC voltage from the piezoelectric layers 6 into a smooth DC voltage. The integrated electronics 7 also have a Zener diode which protects any electrical components from an excessively high voltage and feedback, but is not shown in FIG. 7.

The voltages are then sent from the rectifiers 10 to a DC/DC converter 11, wherein a smoothing capacitor 12 is respectively connected upstream and downstream of the DC/DC converter 11. The DC/DC converter 11 makes it possible to convert the voltages which are coupled out from the rectifiers 10 into another voltage, for example a voltage required for the control unit 2, and to pool this voltage. This makes it possible to operate electrical components in the control unit 2 which cannot be directly operated with the voltage output by the piezoelectric layers 6. The input and output voltage is adapted with the aid of the first smoothing capacitor 12, which is electrically connected upstream of the DC/DC converter 11, and the second smoothing capacitor 12, which is electrically connected downstream of the DC/DC converter 11, using the ratio of the capacitances of the two smoothing capacitors 12.

A suitable voltage can consequently be made available to the control module 4, which may be a system-on-a-chip (SoC) or a microcontroller for example, and an RF module 5. If the electrical components in the control unit 2 require a higher electrical power than can be directly obtained via the piezoelectric layers 6, a rechargeable battery or a capacitor for storing energy can be integrated in the control unit 2. The energy which is extracted with the piezoelectric layers 6 can therefore be stored and accumulated. The collected energy can then be used to enhance the sensors, for example. These may be, for instance, GPS sensors, temperature sensors, force sensors, a humidity sensor or any other sensor.

With respect to the RF module 5, it should be ensured that the RF module 5 preferably has a power-on reset time with a duration of less than 50 ms. An RF module 5 having a short power-on reset time requires less energy in order to ramp up into a functional state. Therefore, RF modules 5 having a short power-on reset time, in particular, are suitable for integration in an energy harvesting system Low-energy Z-wave, ZigBee or Bluetooth modules are expressly suitable as the RF module 5 since they consume little energy and can be controlled via a control module 4.

FIG. 4 is a schematic graph in which the transmission power of a Bluetooth module is plotted against the time. The Bluetooth module has a start-up or power-reset time of approximately 5 ms. The Bluetooth module then alternately transmits on three channels. A cycle through the channels lasts approximately 1.5 ms. In the example shown, three of the 79 possible channels are used. The number of channels can be adapted depending on the required transmission speed, in which case a smaller number is more energy-saving. In one particularly preferred embodiment, transmission is effected only on a single channel in order to provide information transmission which is as energy-efficient as possible. Additionally or alternatively, the energy required during transmission can be reduced by adapting and optimizing the transmission power and the inter-signal pause. In the energy harvesting system with an RF module shown, it is necessary to find a compromise between the energy consumption, the transmission security, the transmission distance and the transmission speed which satisfies the application.

As an alternative to the Zener diode, it is possible to use a protective circuit 17, as shown in FIG. 5, to protect electrical components. This is expedient, in particular, if the rectifier 10 is implemented in an integrated circuit since an excessive voltage can result in irreversible damage in an integrated circuit. A voltage divider comprising the resistors R1 and R2 is connected in parallel with a capacitor C2 which is connected in series with a transistor M1. A voltage is tapped off between the resistors R1 and R2 and is electrically connected to the gate. The voltage divider and the transistor M1 are matched to one another such that an excessive voltage, which could possibly damage an integrated circuit, turns on the transistor M1. In one preferred embodiment, the resistor R1 is ten times as large as the resistor R2. Accordingly, an electrical charge flows to the capacitor C2 and the excessive voltage is reduced. This protects an integrated circuit connected in parallel. Furthermore, the charge may flow away from the capacitor again, after the voltage has been reduced again, and can be used by the energy harvesting system. In contrast to a Zener diode, the excess charge may also easily flow away and electrical induced damping of the mechanical movement of the photoelectric layers may thus be counteracted. A MOSFET can preferably be used as the transistor M1.

FIG. 6 likewise shows a protective circuit 17. A voltage divider comprising the resistor R1 and the resistor R2 is also connected in parallel with a capacitor C1, which is connected in series with a transistor, in this protective circuit 17. In contrast to the circuit in FIG. 4, this is a power MOSFET Q1 which has eight pins and is suitable for higher powers. The gate G which is at the third pin is electrically contact-connected to the voltage divider. The two sources S1 and S2 are at the fourth and seventh pins and are connected to the negative conductor. The five drains of the power MOSFET Q1, which can be tapped off at the remaining pins, are connected to one another via a node and make contact with the capacitor C1 which is in turn connected to the positive line.

FIG. 7 shows the layout of a printed circuit board 18 on which the circuit shown in FIG. 5 is arranged. The printed circuit board 18 has the shape of a circle segment in order to be matched to the shape of a frame 14 to which the printed circuit board 18 can be fastened via a through-hole, which is on the round edge of the printed circuit board 18, by means of a screw connection. The voltage divider is arranged in a manner facing the round edge, wherein the resistor R2 is above the resistor R1. Facing away from the round edge of the printed circuit board 18, the capacitor C1 is arranged above the transistor Q1. Contact is simultaneously made with three of the drain pins of the power MOSFET Q1 via an areal contact.

FIG. 8 shows two sets of integrated electronics 7 which are each installed on a printed circuit board 18 in the form of a circle segment and are connected in parallel with one another to form a group. The piezoelectric layers 6 can usually provide a sufficiently high voltage, while the generated current intensity may be too low for some applications. The current of the integrated electronics 7 can be added and therefore increased by connecting the integrated electronics 7 in parallel with one another. Depending on generated electrical currents and voltages of the piezoelectric layers 6, a plurality of integrated circuits 7 may also be connected in series or in parallel with one another to form groups. A serial or parallel connection of a plurality of groups to one another may also be expedient in order to achieve a required voltage or a required current.

FIG. 9 likewise illustrates a printed circuit board 18 which, like the printed circuit board 18 in FIG. 7, has the form of a circle segment in order to adapt it to the shape of a frame 14. The printed circuit board 18 has two through-holes on the rounded edge, with which it can be fixed to the frame 14 by means of screw connections. In contrast to the embodiments in FIGS. 7 and 8, two sets of integrated electronics 7 are installed on the printed circuit board 18 in FIG. 9 and process the electrical energy from two piezoelectric plates, wherein the two sets of integrated electronics 7 are connected in parallel with one another. An integrated circuit for rectifying the voltage, as in the previous examples, is not used in the integrated electronics 7. Instead, the integrated electronics 7 are used via a circuit having four discrete individual diodes D1-D4. Since discrete individual diodes D1-D4 are much more insensitive to an excessive voltage than an integrated circuit, it is possible to dispense with a Zener diode or a protective circuit 17.

FIG. 10 shows the circuit diagram of the printed circuit board 18 illustrated in FIG. 9. Two bridge rectifiers which are connected in parallel and are each constructed from four discrete individual diodes D1-D4 are involved. The four discrete individual diodes D1-D4 are connected in such a manner that two individual diodes D1-D4 connected in series are respectively connected in parallel with one another. The voltage to be smoothed from the piezoelectric layers 6 is supplied between the individual diodes Dl-D4 connected in series. The positive DC voltage can thus be tapped off in the forward direction of the diodes and the negative DC voltage can be tapped off in the opposite direction to the forward direction. It may be advantageous to also connect a capacitor in parallel with the bridge rectifier or even in parallel with each discrete individual diode D1-D8 in order to obtain a more continuous and more constant voltage or to protect the individual diodes. Rectifier diodes or signal diodes, in particular, are suitable as discrete individual diodes D1-D8.

FIG. 11 shows an arrangement in which 24 piezoelectric layers 6, similar to those in FIG. 1, are fastened in a frame 14. The frame 14 comprises three circles which engage in one another and are each perpendicular to one another. The frame is preferably composed of a non-conductive material, for instance plastic, but may also be made of a metal in the case of high stability requirements. Eight piezoelectric layers 6 are respectively fastened inside one of the three circles which are perpendicular to one another, with the result that the frame 14 accommodates a total of 24 piezoelectric layers 6.

FIG. 12 shows an arrangement in which 24 piezoelectric units 3 are fastened in the frame 14. In comparison to FIG. 11, a limiter 9 and the internal electronics 7 are fitted to each of the piezoelectric layers 6. The limiters 9 are designed to limit the deflection of the piezoelectric layers 6. The limiters 9 in FIG. 5 span half of the piezoelectric layer 6 with a distance of approximately 1 mm, but may cover the entire piezoelectric layer or only a quarter of the piezoelectric layer 6 with a certain distance. The limiter 9 reduces the mechanical load for the piezoelectric layers 6 in the case of strong force influences or during continuous operation. By virtue of the fact that the limiter 9 prevents very severe deflection and therefore severe deformation, undesirable voltage spikes from the piezoelectric layers 6 can be avoided.

FIG. 13 shows a shock sensor 13 in which an energy harvesting system 1 according to the present invention is integrated. In addition to the arrangement shown in FIG. 12, a control unit 2 is installed here, to which the internal electronics 7 are connected. The frame 14 having the integrated energy harvesting system 1 can be closed using cover parts 15 and may be additionally encased with a protective layer, for instance made of leather, rubber or plastic. Such a shock sensor 13 is completely autonomous in terms of energy since all electrical components in the system are operated only with the energy extracted from the piezoelectric layers 6. It is therefore possible to completely dispense with an external energy supply, and so the shock sensor 13 is completely independent and mobile.

The frame 14 of the shock sensor 13 may be reinforced, as illustrated in FIG. 14. The shock sensor 13 is therefore suitable for even greater forces and acceleration, and so it can also generate a greater amount of energy. The reinforcement of the frame 14 is primarily achieved by means of cross-struts 19 which are arranged at the corners of the inter-engaging circles and connect the latter. The cross-struts 19 themselves are also round and have through-holes which can be used to screw cover parts 15.

FIG. 15 shows a holder 20 for the central control unit 2, which is suitable for being installed in the circular shock sensor 13 described. The three outer rods are shaped in such a manner that they fit into an eighth of the spherical shock sensor and can be screwed to each of the three inter-engaging circles. The holder 20 therefore also seriously contributes to the stability of the shock sensor 13. The central control unit 2 can be fastened on the central bonding surface having two through-holes.

FIG. 16 shows a further embodiment of a cover part 15. This embodiment does not have the shape of an eighth of a spherical surface, but rather half a spherical surface. The spherical frame 14 of the shock sensor 13 may therefore already be encased with two cover parts 15 and does not require eight cover parts 15, as in the first embodiment. The shock sensor 13 becomes more robust as a result. The cover part 15 has through-holes with depressions, via which it is screwed to the frame 14 by means of the through-holes in the cross-struts 19 of the frame 14. On that part of the cover part which is above the holder 20 of the central control unit 2 from FIG. 15, the cover part 15 has a multiplicity of through-holes. This means that the signal from the RF module 5 contained in the control unit 2 undergoes less damping.

FIG. 7 shows a schematic sketch of the method of operation of a shock sensor 13. On the left-hand side, before a collision, the sensor does not yet have any energy and therefore cannot transmit any information either. On the right-hand side, after a collision, the shock sensor 13 has obtained sufficient energy, from the vibrations and strong accelerations during impact, to transmit the detected information relating to the impact which has taken place to a receiver 16, here a smartphone, without being dependent on an external energy supply or a battery. The shock sensor 13 can be enhanced with other sensors and can therefore be used in a wide variety of fields of application.

### LIST OF REFERENCE SIGNS

1 Energy harvesting system

2 Control unit

3 Piezoelectric unit

4 Control module

5 RF module

6 Piezoelectric layer

7 Integrated electronics

8 Substrate

9 Limiter

10 Rectifier

11 DC/DC converter

12 Smoothing capacitor

13 Shock sensor

14 Frame

15 Cover part

16 Receiver

17 Protective circuit

18 Printed circuit board

19 Cross-struts

20 solder

R1/R2 Resistor

C1/C2 Capacitor

M1 Transistor

Q1 Power MOSFET

D1-D6 Discrete individual diodes

1. An energy harvesting system comprising:
at least two piezoelectric units each comprising:
a piezoelectric layer, and
integrated electronics,
wherein the integrated electronics make electrical contact with the piezoelectric layer, and
wherein the integrated electronics comprises electrical components for smoothing an electrical voltage generated in the piezoelectric layer;
wherein the piezoelectric layers are arranged at an angle to one another;
a central control unit, with which the integrated electronics make electrical contact,
wherein the control unit comprises a control module and is designed to collect electrical energy from the piezoelectric units, and wherein the control module is designed to minimize or prevent mutual electrical damping of the piezoelectric units.

2. The energy harvesting system according to claim 1, wherein the piezoelectric layers are arranged perpendicular to one another.

3. The energy harvesting system according to claim 1, which comprises a third piezoelectric unit, the piezoelectric layer of which is at an angle to the piezoelectric layers of the first two piezoelectric units.

4. The energy harvesting system according to claim 3,
wherein the piezoelectric layer of the third piezoelectric unit is perpendicular to the piezoelectric layers of the first two piezoelectric units.

5. The energy harvesting system according to claim 3, which comprises further piezoelectric units, the piezoelectric layer of which is at an angle to the other piezoelectric units.

6. The energy harvesting system according to claim 1,
wherein the piezoelectric layers are in the form of circle segments.

7. The energy harvesting system according to claim 1,
wherein the piezoelectric layers are arranged in three intersecting circular planes.

8. The energy harvesting system according to claim 1,
wherein the piezoelectric units and the control unit are fastened in a frame.

9. The energy harvesting system according to claim 1,
wherein the frame is spherical.

10. The energy harvesting system according to claim 1,
wherein the at least two sets of integrated electronics are connected in parallel or in series with one another to form a group.

11. The energy harvesting system according to claim 1,
wherein the energy harvesting system comprises a plurality of connected groups of integrated electronics, and
wherein the groups of integrated electronics are connected in parallel or in series with one another.

12. The energy harvesting system according to claim 1,
wherein the integrated electronics and/or the control unit comprises electrical components for limiting an electrical voltage generated in the piezoelectric layer.

13. The energy harvesting system according to claim 13,
wherein the integrated electronics comprises a rectifier.

14. The energy harvesting system according to claim 13,
wherein the rectifier is constructed from a connection of discrete individual diodes.

15. The energy harvesting system according to claim 13,
wherein the rectifier is integrated in an integrated circuit and a Zener diode is connected in parallel with the integrated circuit.

16. The energy harvesting system according to claim 13,
wherein the rectifier is integrated in an integrated circuit and a protective circuit is connected in parallel with the integrated circuit,
wherein the protective circuit comprises a voltage divider, a transistor and a capacitor,
wherein the transistor and the capacitor are connected in series, and
wherein the voltage divider is connected in parallel with the transistor and the capacitor,
wherein the transistor is controlled by a voltage taken from the voltage divider.

17. The energy harvesting system according to claim 1,
wherein the control unit comprises an RF module.

18. The energy harvesting system according to claim 17,
wherein the control unit and the RF module are designed to be operated with the collected electrical energy.

19. The energy harvesting system according to claim 1,
wherein the energy harvesting system is autonomous in terms of energy.

20. The energy harvesting system according to claim 1,
wherein the piezoelectric layer is arranged on a substrate which is thinner than 1 mm.

21. The energy harvesting system according to claim 20,
wherein the substrate is electrically conductive.

22. The energy harvesting system according to claim 20,
wherein the shape of the piezoelectric layer is adapted to the shape of the substrate.

23. The energy harvesting system according to claim 1,
wherein the piezoelectric units comprise a limiter (9) which is designed to limit the deflection of the piezoelectric layer.

24. The energy harvesting system according to claim 1,
wherein the control unit comprises a DC/DC converter.

25. The energy harvesting system according to claim 1,
wherein the integrated electronics and/or the control unit comprises a smoothing capacitor (12).

26. The energy harvesting system according to claim 1,
wherein the control module is a system-on-a-chip or a microcontroller.

27. The energy harvesting system according to claim 17,
wherein the RF module has a power-on reset time with a duration of less than 50 ms, and/or
wherein the RF module is a Z-wave module, a ZigBee module or a Bluetooth module.

28. The energy harvesting system according to claim 17,
wherein the RF module is a Bluetooth transmitter,
wherein the Bluetooth transmitter is configured to adapt the number of channels.

29. The energy harvesting system according to claim 28,
wherein the Bluetooth transmitter transmits on a single channel.

30. The energy harvesting system according to claim 17,
wherein the duration of a transmission signal, the transmission power and the inter-signal pause are set in such a manner that as little energy as possible is consumed.

31. The energy harvesting system according to claim 1,
wherein the control unit additionally comprises a rechargeable battery or a capacitor for storing energy.

32. The energy harvesting system according to claim 1,
wherein the control unit is configured to determine an acceleration acting on the energy harvesting system in a direction-dependent manner on the basis of the voltages generated in the piezoelectric layers.

33. The energy harvesting system according to claim 1,
wherein the control unit comprises additional sensors.

34. The energy harvesting system according to claim 1,
wherein the piezoelectric layer is a polymer layer, a ceramic layer, a thin ceramic layer, a multilayer ceramic or a monolithic ceramic.

35. The energy harvesting system according to claim 1,
wherein the piezoelectric layer is thinner than 300 μm.

36. A shock sensor comprising:
at least one energy harvesting system according to claim 1,
wherein the energy harvesting system is designed to detect an impact or shock and to transmit this information to a receiver.
